(19) United States
(12) Patent Application Publication
(10) Pub. No.: US 2026/0113936 A1
(43) Pub. Date: Apr. 23, 2026

(54) SEMICONDUCTOR DEVICE AND MANUFACTURING METHOD OF SEMICONDUCTOR DEVICE

(71) Applicant: SK hynix Inc., Icheon-si Gyeonggi-do (KR)

(72) Inventor: Chang Woo KANG, Icheon-si Gyeonggi-do (KR)

(73) Assignee: SK hynix Inc., Icheon-si Gyeonggi-do (KR)

(21) Appl. No.: 19/065,835

(22) Filed: Feb. 27, 2025

(30) Foreign Application Priority Data
Oct. 17, 2024 (KR) 10-2024-0142479

(51) Int. Cl. H10B 41/30; H10B 41/27; H10B 43/27; H10B 43/30

(52) U.S. Cl. CPC H10B 41/30; H10B 41/27; H10B 43/27; H10B 43/30

(57) ABSTRACT

A semiconductor device includes: a first gate structure including first conductive layers; a second gate structure located on the first gate structure and including second conductive layers; first contact vias extending through the second gate structure and into the first gate structure and connected to the first conductive layers, respectively, and each first contact via including a lower via and upper vias merged with each other in a horizontal direction and connected to the lower via; and second contact vias extending at least partially through the second gate structure and connected to the second conductive layers, respectively.

### CROSS-REFERENCE TO RELATED APPLICATION

The present application claims priority under 35 U.S.C. § 119(a) to Korean Patent Application No. 10-2024-0142479 filed on Oct. 17, 2024, in the Korean Intellectual Property Office, which application is incorporated herein by reference in its entirety.

### BACKGROUND

### 1. Technical Field

Embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a first gate structure including first conductive layers; a second gate structure located on the first gate structure and including second conductive layers; first contact vias extending through the second gate structure and into the first gate structure and connected to the first conductive layers, respectively, and each first contact via including a lower via and upper vias merged with each other in a horizontal direction and connected to the lower via; and second contact vias extending at least partially through the second gate structure and connected to the second conductive layers, respectively.

In an embodiment, a semiconductor device may include: a first gate structure including first conductive layers; a second gate structure located on the first gate structure and including second conductive layers; a third gate structure located on the second gate structure and including third conductive layers; first contact vias each including a first lower via extending into the first gate structure and connected to each of the first conductive layers, respectively, and first upper vias extending through the second gate structure and the third gate structure, the first upper vias merged with each other in a horizontal direction, and the first upper vias connected to the first lower via; second contact vias each including a second lower via extending into the second gate structure and connected to each of the second conductive layers, respectively, and second upper vias extending through the third gate structure, the second upper vias merged with each other in the horizontal direction, and the second upper vias connected to the second lower via; and third contact vias extending at least partially through the third gate structure and connected to the third conductive layers, respectively.

In an embodiment, a manufacturing method of a semiconductor device may include: forming a first stack; forming a first via hole extending through the first stack; forming a second stack on the first stack; forming preliminary second via holes extending through the second stack and connected to the first via hole; forming a second via hole by expanding the preliminary second via holes so that the preliminary second via holes are connected to each other; and forming a first contact via in the first via hole and the second via hole.

In an embodiment, a manufacturing method of a semiconductor device may include: forming a first stack; forming a first via hole extending through the first stack; forming a second stack on the first stack; forming preliminary second via holes extending through the second stack and connected to the first via hole; forming a third stack on the second stack; forming preliminary fourth via holes extending through the third stack and connected to the preliminary second via holes; forming a second via hole and a fourth via hole by expanding the preliminary second via holes so that the preliminary second via holes are connected to each other and expanding the preliminary fourth via holes so that the preliminary fourth via holes are connected to each other; and forming a first contact via in the first via hole, the second via hole, and the fourth via hole.

### BRIEF DESCRIPTION OF THE DRAWINGS

FIGS. 1A and 1B are diagrams for describing a semiconductor device in accordance with an embodiment.

FIGS. 2A, 2B, 3A, and 3B are diagrams for describing a semiconductor device in accordance with an embodiment.

FIG. 4 is a diagram for describing a semiconductor device in accordance with an embodiment.

FIGS. 5A, 5B, 6A, 6B, 7A, 7B, 8A, 8B, 9A, and 9B are diagrams for describing a manufacturing method of a semiconductor device in accordance with an embodiment.

FIGS. 10A, 10B, 11A, and 11B are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

According to an embodiment of the present technology, it is possible to provide a semiconductor device having a stable structure and improved reliability.

Hereafter, embodiments in accordance with the technical spirit of the present disclosure will be described with reference to the accompanying drawings. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” “over” “side” “outer” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

The cross-hatching throughout the figures illustrates corresponding or similar areas between the figures rather than indicating the materials associated with the areas.

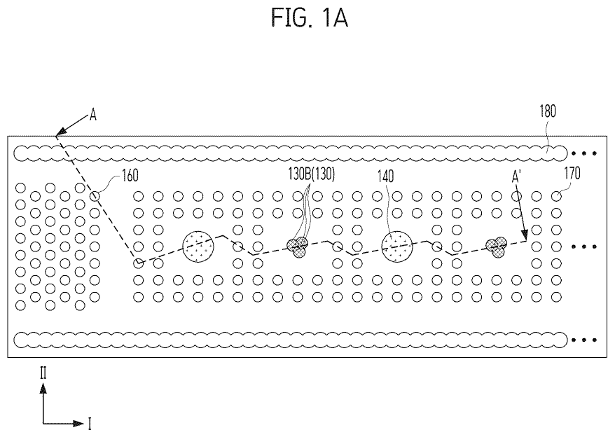

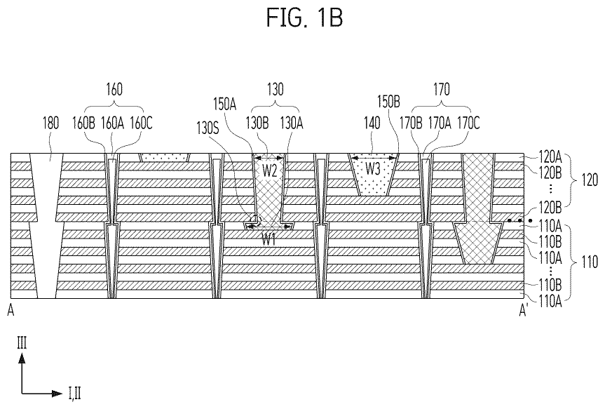

FIGS. 1A and 1B are diagrams for describing a semiconductor device in accordance with an embodiment. FIG. 1A is a plan view, and FIG. 1B is a cross-sectional view taken along line A-A′ of FIG. 1A.

Referring to FIGS. 1A and 1B, the semiconductor device may include a first gate structure 110, a second gate structure 120, first contact vias 130, and second contact vias 140. The semiconductor device may further include first insulating spacers 150A, second insulating spacers 150B, channel structures 160, supports 170, and slit structures 180.

The first gate structure 110 may include first conductive layers 110B. Here, the first conductive layers 110B may extend in a horizontal direction. The first gate structure 110 may include first insulating layers 110A and the first conductive layers 110B that are alternately stacked. The first insulating layers 110A may each include an insulating material such as oxide, and the first conductive layers 110B may each include a conductive material such as tungsten, molybdenum, or polysilicon.

The second gate structure 120 may be located on the first gate structure 110. The second gate structure 120 may include second conductive layers 120B. For example, the second gate structure 120 may include second insulating layers 120A and the second conductive layers 120B that are alternately stacked. The second insulating layers 120A may each include an insulating material such as oxide, and the second conductive layers 120B may each include a conductive material such as tungsten, molybdenum, or polysilicon.

The first conductive layers 110B and the second conductive layers 120B may be gate lines such as source select lines, word lines, or drain select lines. Source select transistors, memory cells, or drain select transistors may be located in regions where the channel structure 160 and the first conductive layers 110B intersect each other and regions where the channel structure 160 and the second conductive layers 120B intersect with each other. For example, at least one source select transistor, a plurality of memory cells, and at least one drain select transistor that are stacked along the channel structure 160 may constitute one memory string.

The first contact vias 130 may extend through the first gate structure 110 and the second gate structure 120. The first contact vias 130 may each include a lower via 130A and upper vias 130B. The lower via 130A may extend through the first gate structure 110 and be connected to each of the first conductive layers 110B. The upper vias 130B may extend through the second gate structure 120 and be connected to the lower via 130A. Here, the upper vias 130B may be merged with each other in the horizontal direction and connected to the lower via 130A. The number of upper vias 130B merged with each other in the horizontal direction may be two or more. Here, the horizontal direction may mean to a first direction I, a second direction II intersecting with the first direction I, or the first direction I and the second direction II.

A cross section of each of the first contact vias 130 may include a tapered shape. For example, a cross section of the lower via 130A may include a tapered shape, and a cross section of the merged upper vias 130B may include a tapered shape. The lower via 130A may have a width that decreases from an upper surface thereof toward a lower surface thereof, and the merged upper vias 130B may have a width that decreases from an upper surface thereof toward a lower surface thereof. Accordingly, the lower via 130A may have a smaller width at the lower surface than at the upper surface, and the merged upper vias 130B may have a smaller width at the lower surface than at the upper surface. The upper surface of the lower via 130A may have a first width W1. The upper surface of the merged upper vias 130B may have a second width W2. Here, the second width W2 may be smaller than the first width W1. In an embodiment, the upper surface of the merged upper vias 130B faces away from the first gate structure 110 and the lower surface of the merged upper vias 130B contacts the upper surface of the lower via 130A. In an embodiment, the lower surface of the lower via 130A faces away from the upper surface of the lower via 130A and contacts a respective first conductive layer 110B. In an embodiment, the upper surface of the merged upper vias 130B is coplanar with the upper surface of the second contact via 140 and the second gate structure 120. In an embodiment, the lower surface of the second contact via 140 faces away from the upper surface of the second contact via 140 and contacts a respective second conductive layer 120B.

The first contact vias 130 may each include an inflection portion 130S located between the first gate structure 110 and the second gate structure 120. For example, the first contact vias 130 may each include an inflection portion 130S located at a boundary surface where the upper surface of the lower via 130A and the lower surface of the merged upper vias 130B are in contact with each other. The inflection portion 130S may have a width changed between the lower via 130A in the first gate structure and the merged upper vias 130B in the second gate structure. In such a case, the first contact vias 130 may each have a width that decreases from the upper surface of the merged upper vias 130B toward the lower surface of the merged upper vias 130B, increases again at the inflection portion 130S, and decreases from the upper surface of the lower via 130A toward the lower surface of the lower via 130A. In other words, at the inflection portion 130S, the width of the merged upper vias 130B in the second gate structure 120 may be smaller than the width of the lower via 130A in the first gate structure 110.

The merged upper vias 130B may constitute irregularities on sidewalls of the first contact vias 130. Here, the irregularities may refer to a shape in which convex portions and concave portions are repeatedly formed on the sidewalls while the upper vias 130B are merged with each other. For example, contact portions between the upper vias 130B may form the concave portions of the irregularities, and the upper vias 130B may form the convex portions of the irregularities. The first contact vias 130 may each include a conductive material such as tungsten.

The second contact vias 140 may extend through the second gate structure 120, and may be connected to the second conductive layers 120B, respectively. A cross section of each of the second contact vias 140 may include a tapered shape. An upper surface of each of the second contact vias 140 may have a third width W3. Here, the third width W3 may be substantially the same as the first width W1. The second contact vias 140 may each include a conductive material such as tungsten.

In order to improve the degree of integration in an embodiment of the semiconductor device, the number of first conductive layers 110B of the first gate structure 110 and the number of second conductive layers 120B of the second gate structure 120 may increase. In such a case, the numbers of first contact vias 130 and second contact vias 140 respectively connected to the first conductive layers 110B and the second conductive layers 120B may also increase. Accordingly, in an embodiment, it is necessary to efficiently dispose the first contact vias 130 and the second contact vias 140 in consideration of widths, intervals, and the like, of the first contact vias 130 and the second contact vias 140.

The first contact vias 130 may be connected to the first conductive layers 110B of the first gate structure 110, respectively, and the second contact vias 140 may be connected to the second conductive layers 120B of the second gate structure 120, respectively. The first contact vias 130 may respectively include the lower vias 130A having a relatively greater width than the width of the merged upper vias 130B. Because, in an embodiment, the lower vias 130A may have a relatively greater width than the upper vias 130B, the lower vias 130A may be in contact with the first conductive layers 110B over a greater area than would be for only having the upper vias 130B contact with the first conductive layers 110B, and electrical connectivity between the lower vias 130A and the first conductive layers 110B may be increased over simply using the upper vias 130B. Likewise, because, in an embodiment, the second contact vias 140 may have a similar width to the lower vias 130A, the second contact vias 140 may be in contact with the second conductive layers 120B over a greater area as compared to simply using the upper vias 130B, and electrical connectivity between the second contact vias 140 and the second conductive layers 120B may be increased over simply using the upper vias 130B.

In order to continuously arrange the first contact vias 130 in the horizontal direction, it is necessary to secure a space margin between regions where the lower vias 130A having the relatively great width as compared to the width of the upper vias 130B re to be formed. In addition, as the number of first contact vias 130 increases, a required space margin may also increase. Likewise, in order to continuously arrange the second contact vias 140 in the horizontal direction, it is necessary to secure a space margin between regions where the second contact vias 140 having a relatively great width as compared to the upper vias 130B re to be formed. In addition, as the number of second contact vias 140 increases, a required space margin may also increase. Accordingly, in an embodiment, when the first contact vias 130 are continuously arranged in the horizontal direction and the second contact vias 140 are continuously arranged in the horizontal direction, there is a limitation in improving the degree of integration of the semiconductor device.

According to an embodiment of the present disclosure, the first contact vias 130 and the second contact vias 140 may be alternately arranged in the horizontal direction. In other words, the first contact vias 130 including the lower vias 130A having the relatively greater width as compared to the upper vias 130B may be arranged to be spaced apart from each other, and the second contact vias 140 having the relatively greater width as compared to the upper vias 130B may be located between the first contact vias 130. Because, in an embodiment, the merged upper vias 130B of the first contact vias 130 have a smaller width than the lower vias 130A, a space margin for locating the second contact vias 140 may be secured. In other words, in an embodiment, by forming the merged upper vias 130B having a relatively smaller width than the width of the lower vias 130A in a process of manufacturing the semiconductor device, a space margin for locating the second contact vias 140 having the relatively greater width than the upper vias 130B may be secured. Accordingly, in an embodiment, the degree of integration of the semiconductor device may be improved.

The first insulating spacers 150A may extend through the first gate structure 110 and the second gate structure 120, and may surround the sidewalls of the first contact vias 130, respectively. The first insulating spacer 150A may insulate the remaining first conductive layers 110B except for the first conductive layer 110B connected to the first contact via 130 and the first contact via 130 from each other. The first insulating spacers 150A may each include an insulating material such as oxide.

The second insulating spacers 150B may extend through the second gate structure 120, and may surround sidewalls of the second contact vias 140, respectively. The second insulating spacer 150B may insulate the remaining second conductive layers 120B except for the second conductive layer 120B connected to the second contact via 140 and the second contact via 140 from each other The second insulating spacers 150B may each include an insulating material such as oxide.

The channel structures 160 may extend through the first gate structure 110 and the second gate structure 120. The channel structures 160 may each include a channel layer 160A and a memory layer 160B surrounding the channel layer 160A. The channel structures 160 may each further include an insulating core 160C located in the channel layer 160A Here, the channel layer 160A may include a semiconductor material such as polysilicon or germanium. The insulating core 160C may include an insulating material such as oxide.

The supports 170 may be spaced apart from the channel structures 160, and may extend through the first gate structure 110 and the second gate structure 120. The supports 170 may be located around the first contact vias 130 and the second contact vias 140. For example, in an embodiment, the supports 170 may be located around the first contact vias 130 and the second contact vias 140, respectively, as shown in FIG. 1A. The supports 170 may each have a similar structure to the channel structures 160. For example, the supports 170 may each include a dummy channel layer 170A and a dummy memory layer 170B surrounding the dummy channel layer 170A. The supports may each further include a dummy insulating core 170C located in the dummy channel layer 170A. However, the present disclosure is not limited thereto, and the supports 170 may each include a single layer including an insulating material such as oxide. In addition, the supports 170 may each include tungsten oxide or the like.

The slit structures 180 may extend through the first gate structure 110 and the second gate structure 120. In an embodiment, the slit structure 180 may be used as a passage for forming the first gate structure 110, the second gate structure 120, and the like, in the process of manufacturing the semiconductor device. Each of the slit structures 180 may include irregularities on sidewalls thereof. For example, the irregularities of the slit structures 180 may include concave portions and convex portions. The slit structure 180 may include an insulating material, a conductive material, or a semiconductor material.

According to an embodiment of the structure described above, the first contact vias 130 including the lower vias 130A and the second contact vias 140 may be alternately arranged in the horizontal direction. Because, in an embodiment, the merged upper vias 130B of the first contact vias 130 have the smaller width than the lower vias 130A, the space margin for locating the second contact vias 140 may be secured. Accordingly, in an embodiment, the degree of integration of the semiconductor device may be improved.

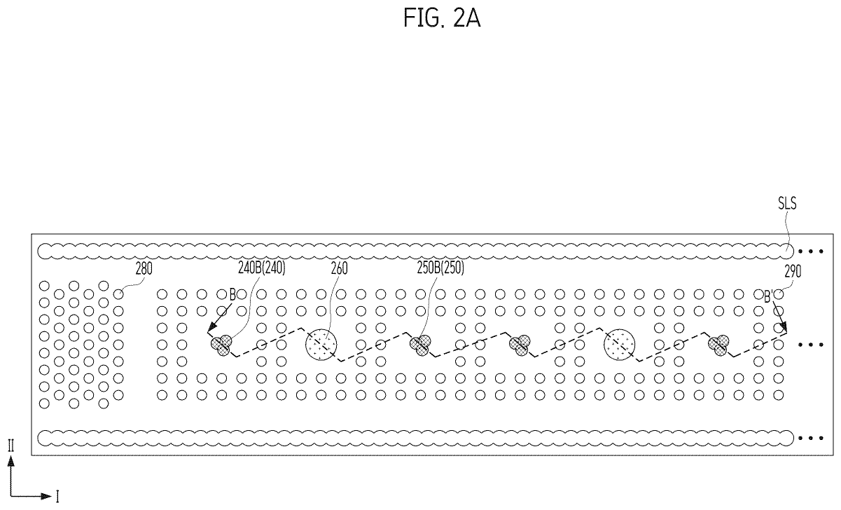

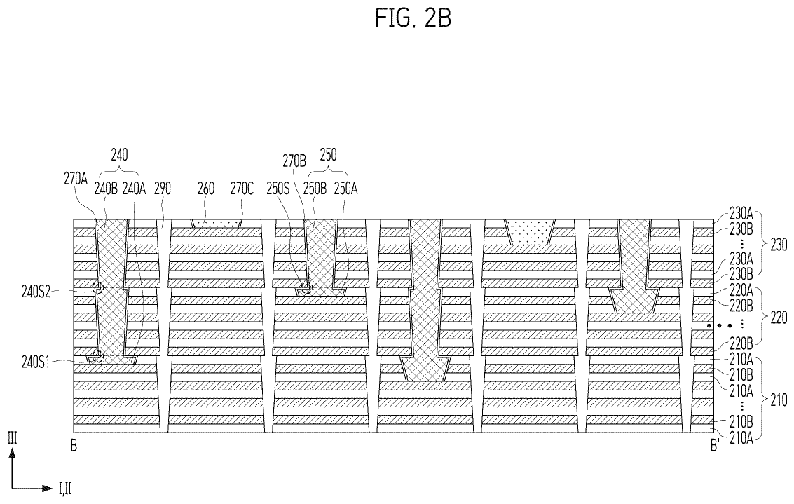

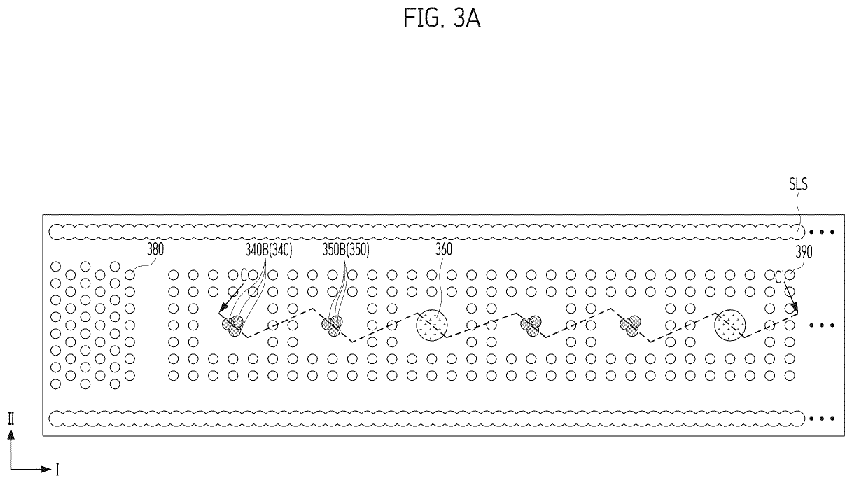

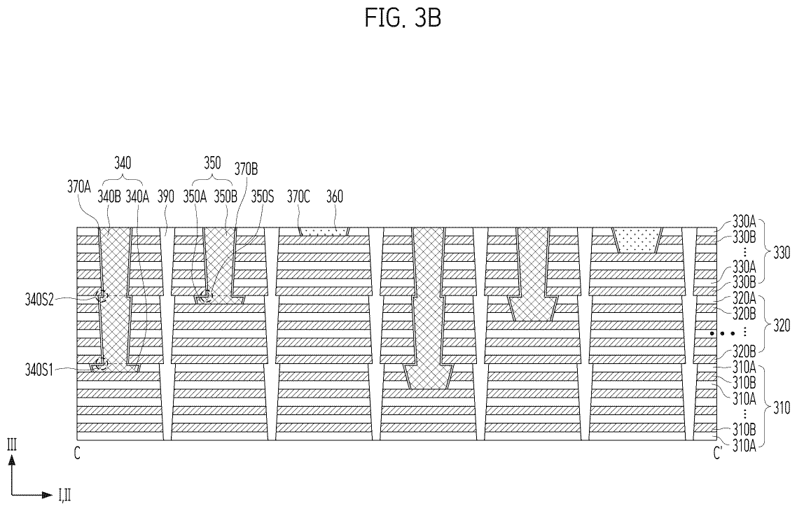

FIGS. 2A, 2B, 3A, and 3B are diagrams for describing a semiconductor device in accordance with an embodiment. FIGS. 2A and 3A are plan views, FIG. 2B is a cross-sectional view taken along line B-B′ of FIG. 2A, and FIG. 3B is a cross-sectional view taken along line C-C′ of FIG. 3A. Hereinafter, the content overlapping with the previously described content will be omitted.

Referring to FIGS. 2A, 2B, 3A, and 3B, the semiconductor device may include a first gate structure 210 or 310, a second gate structure 220 or 320, a third gate structure 230 or 330, first contact vias 240 or 340, second contact vias 250 or 350, and third contact vias 260 or 360. The semiconductor device may further include first insulating spacers 270A or 370A, second insulating spacers 270B or 370B, third insulating spacers 270C or 370C, channel structures 280 or 380, supports 290 or 390, and slit structures SLS.

The first gate structure 210 or 310 may include first insulating layers 210A or 310A and first conductive layers 210B or 310B that are alternately stacked. The second gate structure 220 or 320 may be located on the first gate structure 210 or 310. The second gate structure 220 or 320 may include second insulating layers 220A or 320A and second conductive layers 220B or 320B that are alternately stacked. The third gate structure 230 or 330 may be located on the second gate structure 220 or 320. The third gate structure 230 or 330 may include third insulating layers 230A or 330A and third conductive layers 230B or 330B that are alternately stacked.

The first contact vias 240 or 340 may extend into the first gate structure 210 or 310, through the second gate structure 220 or 320, and through the third gate structure 230 or 330. The first contact vias 240 or 340 may each include a first lower via 240A or 340A and first upper vias 240B or 340B. The first lower via 240A or 340A may extend through the first gate structure 210 or 310 and be connected to each of the first conductive layers 210B or 310B, respectively. The first upper vias 240B or 340B may extend through the second gate structure 220 or 320 and the third gate structure 230 or 330 and be connected to the first lower via 240A or 340A. Here, the first upper vias 240B or 340B may be merged with each other in the horizontal direction and connected to the first lower via 240A or 340A.

The number of first upper vias 240B or 340B merged with each other in the horizontal direction may be two or more. The merged first upper vias 240B or 340B may constitute irregularities on sidewalls of the first contact vias 240 or 340. A width of an upper surface of the merged first upper vias 240B or 340B may be smaller than a width of an upper surface of the first lower via 240A or 340A.

The second contact vias 250 or 350 may extend through the third gate structure 230 or 330 and into the second gate structure 220 or 320. The second contact vias 250 or 350 may each include a second lower via 250A or 350A and second upper vias 250B or 350B. The second lower via 250A or 350A may extend through the second gate structure 220 or 320 and be connected to each of the second conductive layers 220B or 320B, respectively. The second upper vias 250B or 350B may extend through the third gate structure 230 or 330 and be connected to the second lower via 250A or 350A. Here, the second upper vias 250B or 350B may be merged with each other in the horizontal direction and connected to the second lower via 250A or 350A.

The number of second upper vias 250B or 350B merged with each other in the horizontal direction may be two or more. The merged second upper vias 250B or 350B may constitute irregularities on sidewalls of the second contact vias 250 or 350. A width of an upper surface of the merged second upper vias 250B or 350B may be smaller than a width of an upper surface of the second lower via 250A or 350A. In an embodiment, an upper surface of the merged second upper vias 250B or 350B may be coplanar with an upper surface of the first upper via 240B or 340B and an upper surface of the third contact via 260 or 360. In an embodiment, an upper surface of the merged second upper vias 250B or 350B may face away from the first and second gate structures 220, 320, 210, or 310. In an embodiment an upper surface of the second lower via 250A or 350A may face the third gate structure 230 or 330 and away from the first gate structure 210 or 310. The width of the upper surface of the merged second upper vias 250B or 350B may be substantially the same as the width of the upper surface of the merged first upper vias 240B or 340B.

The first contact vias 240 or 340 may each include a first inflection portion 240S1 or 340S1 located between the first gate structure 210 or 310 and the second gate structure 220 or 320, and may each include a second inflection portion 240S2 or 340S2 located between the second gate structure 220 or 320 and the third gate structure 230 or 330.

The first inflection portion 240S1 or 340S1 may have a width changed between the first lower via 240A or 340A in the first gate structure 210 or 310 and the merged first upper vias 250B or 350B in the second gate structure 220 or 320. The second inflection portion 240S2 or 340S2 may have a width changed between the second gate structure 220 or 320 and the third gate structure 230 or 330. In other words, a width of the merged first upper vias 240B or 340B may be changed at the second inflection portion 240S2 or 340S2. For example, the width of the merged first upper vias 240B or 340B may be changed at a boundary surface where the second gate structure 220 or 320 and the third gate structure 230 or 330 are in contact with each other.

The first contact vias 240 or 340 may each have a width that decreases from the upper surface of the merged first upper vias 240B or 340B toward the second inflection portion 240S2 or 340S2, increases again at the second inflection portion 240S2 or 340S2, decreases from the second inflection portion 240S2 or 340S2 toward a lower surface of the first upper vias 240B or 340B, increases again at the first inflection portion 240S1 or 340S1, and decreases from the upper surface of the first lower via 240A or 340A toward a lower surface of the first lower via 240A or 340A. In other words, at the first inflection portion 240S1 or 340S1, the width of the merged first upper vias 240B or 340B in the second gate structure 220 or 320 may be smaller than the width of the first lower via 240A or 340A in the first gate structure 210 or 310.

The second contact vias 250 or 350 may each include a third inflection portion 250S or 350S located between the second gate structure 220 or 320 and the third gate structure 230 or 330. Here, the third inflection portion 250S or 350S may be located at a level corresponding to the second inflection portion 240S2 or 340S2.

The third inflection portion 250S or 350S may have a width changed between the second gate structure 220 or 320 and the third gate structure 230 or 330. For example, the third inflection portion 250S or 350S may have a width changed between the second lower via 250A or 350A in the second gate structure 220 or 320 and the second upper vias 250B or 350B in the third gate structure 230 or 330. In such a case, the second contact vias 250 or 350 may each have a width that decreases from the upper surface of the merged second upper vias 250B or 350B toward a lower surface of the merged second upper vias 250B or 350B, increases again at the third inflection point 250S or 350S, and decreases from the upper surface of the second lower via 250A or 350A toward a lower surface of the second lower via 250A or 350A. In other words, the merged second upper vias 250B or 350B may have a smaller width at the lower surface than at the upper surface, and the second lower via 250A or 350A may have a smaller width at the lower surface than at the upper surface.

The third contact vias 260 or 360 may extend through the third gate structure 230 or 330, and may be connected to the third conductive layers 230B or 330B, respectively. A width of an upper surface of the third contact vias 260 or 360 may be substantially the same as the width of the upper surface of the first lower via 240A or 340A of the first contact vias 240 or 340 or the width of the upper surface of the second lower via 250A or 350A of the second contact vias 250 or 350.

According to an embodiment of the present disclosure, an arrangement of the form of the contact vias may be variously changed depending on the number of gate structures and the number of conductive layers. However, the arrangement of the form of the contact vias is not limited to arrangement forms of an embodiment of FIGS. 2A, 2B, 3A, and 3B, and it is also possible to combine such arrangement forms with each other.

As an example, referring to FIGS. 2A and 2B, the third contact via 260 connected to the third conductive layer 230B of the third gate structure 230 may be located between the first contact via 240 connected to the first conductive layer 210B of the first gate structure 210 and the second contact via 250 connected to the second conductive layer 220B of the second gate structure 220. In other words, in the horizontal direction, the first contact via 240 connected to the first gate structure 210, the third contact via 260 connected to the third gate structure 230, and the second contact via 250 connected to the second gate structure 220 may be sequentially arranged.

As another example, referring to FIGS. 3A and 3B, in the horizontal direction, the first contact via 340 connected to the first conductive layer 310B of the first gate structure 310, the second contact via 350 connected to the second conductive layer 320B of the second gate structure 320, and the third contact via 360 connected to the third conductive layer 330B of the third gate structure 330 may be sequentially arranged.

According to an embodiment of the present disclosure, the first lower vias 240A or 340A in the first gate structure 210 or 310 might not be continuously arranged, the second lower vias 250A or 350A in the second gate structure 220 or 320 might not be continuously arranged, and the third contact vias 260 or 360 in the third gate structure 230 or 330 might not be continuously arranged. In other words, by combining the first lower vias 240A or 340A, the second lower vias 250A or 350A, and the third contact vias 260 or 360 having widths of the upper surfaces are relatively great with each other and arranging the combined first lower vias 240A or 340A, second lower vias 250A or 350A, and third contact vias 260 or 360 in the horizontal direction, a space margin between adjacent first lower vias 240A or 340A may be secured, a space margin between adjacent second lower vias 250A or 350A may be secured, and a space margin between adjacent third contact vias 260 or 360 may be secured. Accordingly, in an embodiment, the degree of integration of the semiconductor device may be improved.

For reference, an embodiment for three gate structures has been illustrated in FIGS. 2A, 2B, 3A, and 3B, but the present disclosure may also be applied to four or more gate structures. For example, a fourth gate structure may be located on the third gate structure 230 or 330, and fourth contact vias respectively connected to fourth conductive layers of the fourth gate structure may be located. Here, the third contact vias 260 or 360 may each constitute a third lower via, and merged third upper vias may be located on the third lower via. In such a case, the first lower vias 240A or 340A, the second lower vias 250A or 350A, the third lower vias, and the fourth contact vias may be combined with each other and arranged in the horizontal direction.

The first insulating spacers 270A or 370A may surround the sidewalls of the first contact vias 240 or 340, the second insulating spacers 270B or 370B may surround the sidewalls of the second contact vias 250 or 350, and the third insulating spacers 270C or 370C may surround sidewalls of the third contact vias 260 or 360.

The channel structures 280 or 380 may extend through the first gate structure 210 or 310, the second gate structure 220 or 320, and the third gate structure 230 or 330. The channel structures 280 or 380 may each include a channel layer, a memory layer surrounding the channel layer, and an insulating core located in the channel layer.

The supports 290 or 390 may be spaced apart from the channel structures 280 or 380, and may extend through the first gate structure 210 or 310, the second gate structure 220 or 320, and the third gate structure 230 or 330. The supports 290 or 390 may each have a similar structure to the channel structures 280 or 380.

The slit structures SLS may extend through the first gate structure 210 or 310, the second gate structure 220 or 320, and the third gate structure 230 or 330. The slit structure SLS may be used as a passage for forming the first gate structure 210 or 310, the second gate structure 220 or 320, the third gate structure 230 or 330, and the like, in a process of manufacturing the semiconductor device.

According to an embodiment of the structure described above, when the number of gate structures increases, the arrangement form of the contact vias may be modified. Through this, in an embodiment, a space margin between structures located in the same gate structure and having a relatively great width at an upper surface may be secured. Accordingly, in an embodiment, the degree of integration of the semiconductor device may be improved.

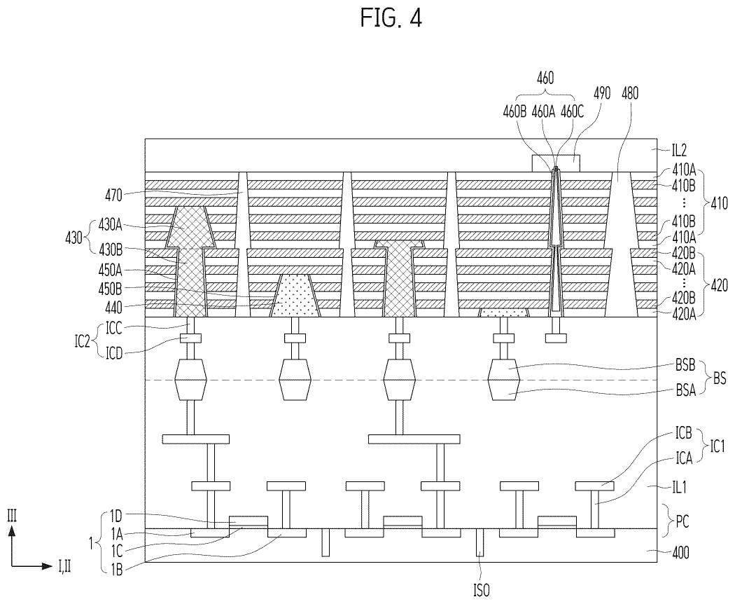

FIG. 4 is a diagram for describing a semiconductor device in accordance with an embodiment. Hereinafter, the content overlapping with the previously described content will be omitted.

Referring to FIG. 4, the semiconductor device may include a first gate structure 410, a second gate structure 420, first contact vias 430, second contact vias 440, a peripheral circuit PC, a bonding structure BS, and a source structure 490. The semiconductor device may further include a substrate 400, a first interconnection structure IC1, a second interconnection structure IC2, an element isolation layer ISO, a first interlayer insulating layer IL1, a second interlayer insulating layer IL2, first insulating spacers 450A, second insulating spacers 450B, a channel structure 460, supports 470, and slit structures 480.

The peripheral circuit PC may be located on the substrate 400. The peripheral circuit PC may include a transistor 1. The transistor 1 may include junctions 1A and 1B, a gate electrode 1D, and a gate insulating layer 1C. Here, the gate insulating layer 1C may be located between the gate electrode 1D and the substrate 400. The element isolation layer ISO may be located in the substrate 400, and an active region of the transistor 1 may be defined by the element isolation layer ISO.

The first interconnection structure IC1 may be located in the first interlayer insulating layer IL1. Here, the first interlayer insulating layer IL1 may be located on the substrate 400. The first interconnection structure IC1 may include first vias ICA and first wiring lines ICB. The first interconnection structure IC1 may be connected to the peripheral circuit PC. For example, at least one of the first vias ICA may be connected to the transistor 1. At least one of the first vias ICA may connect the first wiring lines ICB to each other. The first wiring lines ICB may connect the first vias ICA to each other. The first interconnection structure IC1 may include a conductive material such as tungsten, copper, or aluminum. The first interlayer insulating layer IL1 may include an insulating material such as oxide or nitride.

The bonding structure BS may be located on the peripheral circuit PC. The bonding structure BS may be located in the first interlayer insulating layer IL1. The bonding structure BS may include first bonding pads BSA and second bonding pads BSB. Here, the second bonding pads BSB may be located on the first bonding pads BSA, respectively, and may be connected to the first bonding pads BSA, respectively. The bonding structure BS may include a conductive material such as copper.

The second interconnection structure IC2 may be located on the bonding structure BS. The second interconnection structure IC2 may be located in the first interlayer insulating layer IL1. The second interconnection structure IC2 may include second vias ICC and second wiring lines ICD. The second interconnection structure IC2 may be connected to the bonding structure BS. For example, at least one of the second vias ICC may be connected to the second bonding pad BSB. The second wiring lines ICD may connect the second vias ICC to each other. The second interconnection structure IC2 may include a conductive material such as tungsten, copper, or aluminum.

The second gate structure 420 may be located on the second interconnection structure IC2. The first gate structure 410 may be located on the second gate structure 420. The first gate structure 410 may include first insulating layers 410A and first conductive layers 410B that are alternately stacked, and the second gate structure 420 may include second insulating layers 420A and second conductive layers 420B that are alternately stacked.

The first contact vias 430 may extend through the first gate structure 410 and the second gate structure 420. The first contact vias 430 may each include a lower via 430A extending through the first gate structure 410 and connected to each of the first conductive layers 410B and upper vias 430B extending through the second gate structure 420 and connected to the lower via 430A. Here, the upper vias 430B may be merged with each other in the horizontal direction. A width of an upper surface of the lower via 430A may be greater than a width of an upper surface of the merged upper vias 430B.

The second contact vias 440 may extend through the second gate structure 420, and may be connected to the second conductive layers 420B, respectively. A width of an upper surface of each of the second contact vias 440 may be substantially the same as the width of the upper surface of the lower via 430A of each of the first contact vias 430.

For reference, a cell wafer including the first and second gate structures 410 and 420 and the first and second contact vias 430 and 440 of FIG. 4 may have a form similar to a form in which the structures of FIG. 1B are upside down. For example, the first gate structure 410 and the second gate structure 420 of FIG. 4 may correspond to the first gate structure 110 and the second gate structure 120 of FIG. 1B, respectively. In addition, the first and second contact vias 430 and 440 of FIG. 4 may correspond to the first and second contact vias 130 and 140 of FIG. 1B, respectively. In consideration of this, for convenience of explanation, a portion located at a relatively upper portion in the first contact vias 430 has been described as the lower via 430A, and a portion located at a relatively lower portion in the first contact vias 430 has been described as the upper via 430B. In addition, lower surfaces of the first and second contact vias 430 and 440 have been described as the upper surfaces.

According to an embodiment of the present disclosure, the bonding structure BS may be located between the peripheral circuit PC and the first and second contact vias 430 and 440. In other words, in a process of manufacturing the semiconductor device, a peripheral circuit wafer including the peripheral circuit PC and the cell wafer including the first and second contact vias 430 and 440 may be bonded to each other.

When, in an embodiment, the first contact vias 430 are continuously arranged in the horizontal direction or the second contact vias 440 are continuously arranged in the horizontal direction, an area occupied by the first and second contact vias 430 and 440 in a bonding wafer may increase. Accordingly, in an embodiment, there is a limitation in improving the degree of integration of the semiconductor device.

However, according to an embodiment of the present disclosure, the first contact vias 430 and the second contact vias 440 may be alternately arranged in the horizontal direction. In such a case, in an embodiment, the area occupied by the first and second contact vias 430 and 440 may be reduced compared to the case where the first contact vias 430 are continuously arranged or the second contact vias 440 are continuously arranged. Accordingly, n an embodiment, the degree of integration of the semiconductor device may be improved.

The first insulating spacers 450A may surround sidewalls of the first contact vias 430, and the second insulating spacers 450B may surround sidewalls of the second contact vias 440.

The channel structure 460 may extend through the first gate structure 410 and the second gate structure 420. The channel structure 460 may include a channel layer 460A, a memory layer 460B surrounding the channel layer 460A, and an insulating core 460C located in the channel layer 460A.

The supports 470 may be spaced apart from the channel structure 460, and may extend through the first gate structure 410 and the second gate structure 420. The supports 470 may each have a similar structure to the channel structure 460.

The slit structures 480 may extend through the first gate structure 410 and the second gate structure 420. The slit structure 480 may be used as a passage for forming the first gate structure 410, the second gate structure 420, and the like, in the process of manufacturing the semiconductor device.

The source structure 490 may be located on the first gate structure 410 and the second gate structure 420. The source structure 490 may be located in the second interlayer insulating layer IL2. Here, the second interlayer insulating layer IL2 may be located on the first gate structure 410. The source structure 490 may be connected to the channel structure 460. For example, the source structure 490 may be connected to the channel layer 460A of the channel structure 460. The second interlayer insulating layer IL2 may include an insulating material such as oxide.

According to the structure described above, the first contact vias 430 and the second contact vias 440 may be alternately arranged in the horizontal direction. In such an embodiment, the area occupied by the first and second contact vias 430 and 440 in the wafer may be reduced, and the degree of integration of the semiconductor device may be improved.

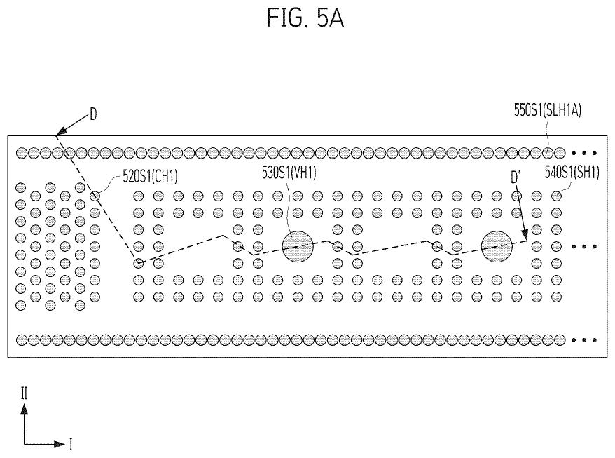

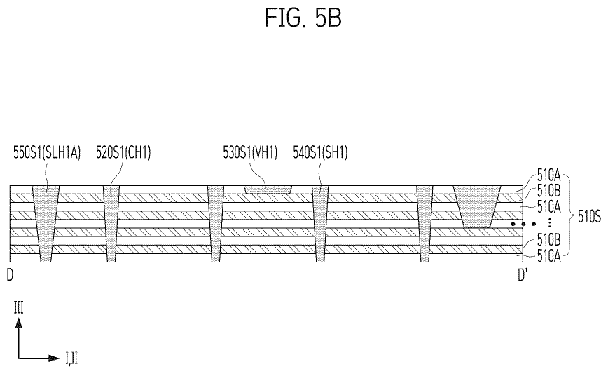

FIGS. 5A, 5B, 6A, 6B, 7A, 7B, 8A, 8B, 9A, and 9B are diagrams for describing a manufacturing method of a semiconductor device in accordance with an embodiment. FIGS. 5A, 6A, 7A, 8A, and 9A are plan views, and FIGS. 5B, 6B, 7B, 8B, and 9B are cross-sectional views taken along lines D-D′ of FIGS. 5A, 6A, 7A, 8A, and 9A, respectively. Hereinafter, the content overlapping with the previously described content will be omitted.

Referring to FIGS. 5A and 5B, a first stack 510S may be formed by alternately stacking first insulating layers 510A and first sacrificial layers 510B. The first insulating layers 510A may each include an insulating material such as oxide, and the first sacrificial layers 510B may each include a sacrificial material such as nitride.

Subsequently, a first channel hole CH1 extending through the first stack 510S may be formed. A first support hole SH1 extending through the first stack 510S may be formed. A first slit hole SLH1A extending through the first stack 510S may be formed. When the first channel hole CH1 is formed, the first support hole SH1 and the first slit hole SLH1A may be formed. For example, the first channel hole CH1 is formed over a first interval of time and the first support hole SH1 and the first slit hole SLH1A is formed over a second interval of time. The first and second intervals of time at least partially overlap each other. Hereinafter, “when A is formed, B may be formed” may interpret as the “A is formed over a first interval of time and the B is formed over a second interval of time, and the first and second intervals of time at least partially overlap each other”. Subsequently, a first channel sacrificial layer 520S1, a first support sacrificial layer 540S1, and a first slit sacrificial layer 550S1 may be formed respectively by forming a sacrificial material such as carbon or tungsten in the first channel hole CH1, the first support hole SH1, and the first slit hole SLH1A.

First via holes VH1 extending through the first stack 510S may be formed. For example, the first via holes VH1 respectively exposing the first sacrificial layers 510B of the first stack 510S may be formed. Subsequently, a first via sacrificial layer 530S1 may be formed by forming a sacrificial material such as carbon or tungsten in the first via hole VH1.

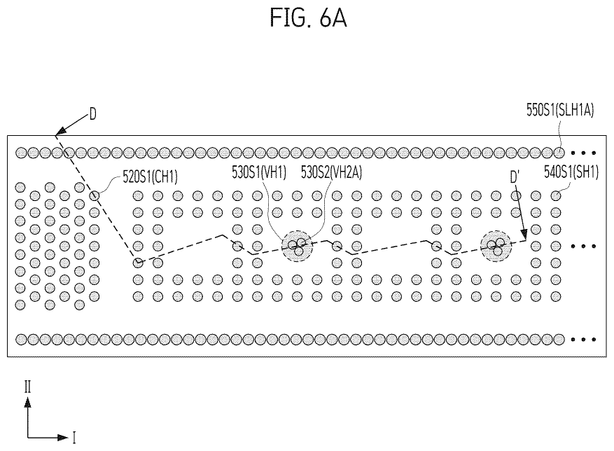

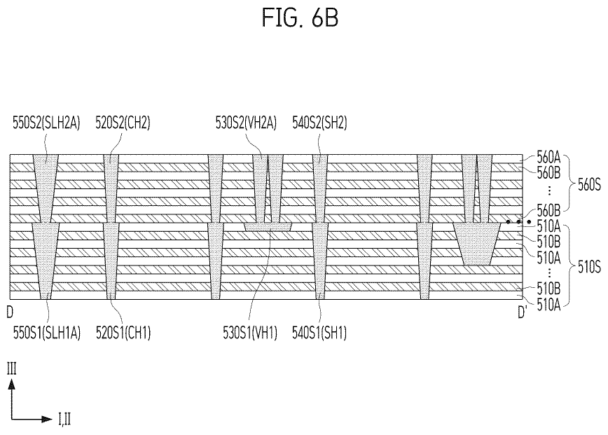

Referring to FIGS. 6A and 6B, a second stack 560S may be formed on the first stack 510S. For example, the second stack 560S may be formed by alternately stacking second insulating layers 560A and second sacrificial layers 560B on the first stack 510S. The second insulating layers 560A may each include an insulating material such as oxide, and the second sacrificial layers 560B may each include a sacrificial material such as nitride.

Subsequently, preliminary second via holes VH2A extending through the second stack 560S may be formed. For example, the preliminary second via holes VH2A connected to the first via hole VH1 may be formed in the second stack 560S. In other words, the preliminary second via holes VH2A exposing the first via sacrificial layer 530S1 may be formed. Here, a width of the preliminary second via holes VH2A may be smaller than a width of the first via hole VH1. The number of preliminary second via holes VH2A may be two or more.

A second channel hole CH2 connected to the first channel hole CH1 may be formed in the second stack 560S. In other words, the second channel hole CH2 exposing the first channel sacrificial layer 520S1 may be formed. A second support hole SH2 connected to the first support hole SH1 may be formed in the second stack 560S. In other words, the second support hole SH2 exposing the first support sacrificial layer 540S1 may be formed. A second slit hole SLH2A connected to the first slit hole SLH1A may be formed in the second stack 560S. In other words, the second slit hole SLH2A exposing the first slit sacrificial layer 550S1 may be formed.

When the second channel hole CH2 is formed, the preliminary second via holes VH2A may be formed. When the second channel hole CH2 is formed, the second support hole SH2 and the second slit hole SLH2A may be formed. In such an embodiment, a manufacturing cost of the semiconductor device may be reduced by unifying processes of forming the second channel hole CH2, the preliminary second via holes VH2A, the second support hole SH2, and the second slit hole SLH2A.

Subsequently, a second channel sacrificial layer 520S2, second via sacrificial layers 530S2, a second support sacrificial layer 540S2, and a second slit sacrificial layer 550S2 may be formed respectively by forming a sacrificial material such as carbon or tungsten in the second channel hole CH2, the preliminary second via holes VH2A, the second support hole SH2, and the second slit hole SLH2A.

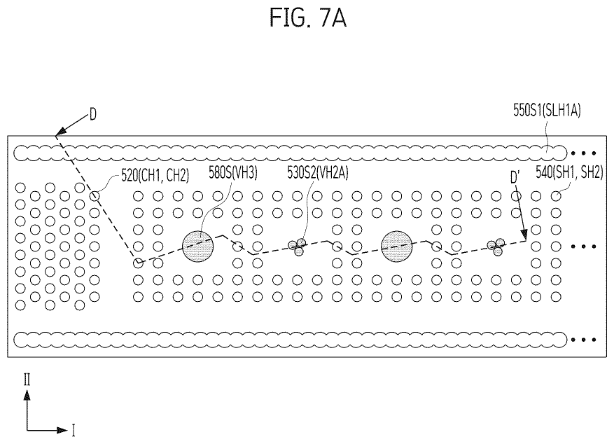

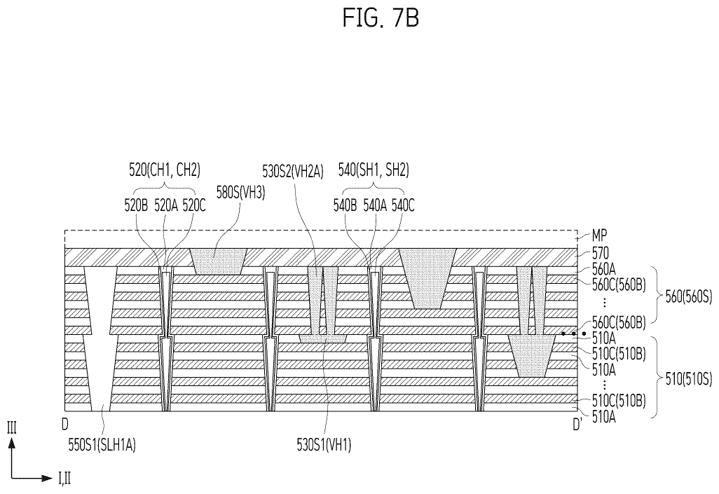

Referring to FIGS. 7A and 7B, the first and second channel holes CH1 and CH2 and the first and second support holes SH1 and SH2 may be reopened by removing the first and second channel sacrificial layers 520S1 and 520S2 and the first and second support sacrificial layers 540S1 and 540S2. Subsequently, a channel structure 520 may be formed in the first and second channel holes CH1 and CH2. For example, a memory layer 520B, a channel layer 520A, and an insulating core 520C may be formed in the first and second channel holes CH1 and CH2. A support 540 may be formed in the first and second support holes SH1 and SH2. For example, a dummy memory layer 540B, a dummy channel layer 540A, and a dummy insulating core 540C may be formed in the first and second support holes SH1 and SH2. In such a case, when the memory layer 520B, the channel layer 520A, and the insulating core 520C are formed, the dummy memory layer 540B, the dummy channel layer 540A, and the dummy insulating core 540C may be formed. However, the present disclosure is not limited thereto, and an insulating material such as oxide may be formed in the first and second support holes SH1 and SH2. Tungsten oxide or the like may be formed in the first and second support holes SH1 and SH2.

The first and second slit holes SLH1A and SLH2A may be reopened by removing the first and second slit sacrificial layers 550S1 and 550S2. Subsequently, the first slit holes SLH1A may be expanded so that the first slit holes SLH1A are connected to each other, and the second slit holes SLH2A may be expanded so that the second slit holes SLH2A are connected to each other. Consequently, one slit SL may be formed. Subsequently, a slit structure 550 may be formed in the slit SL. Here, the slit structure 550 may include an insulating material, a conductive material, a semiconductor material, or the like.

Before the slit structure 550 is formed, the first sacrificial layers 510B of the first stack 510S and the second sacrificial layers 560B of the second stack 560S may be replaced with first conductive layers 510C and second conductive layers 560C, respectively. For example, openings may be formed by removing the first sacrificial layers 510B and the second sacrificial layers 560B through the slit SL. Subsequently, the first conductive layers 510C and the second conductive layers 560C may be formed respectively by forming a conductive material in the openings. Consequently, a first gate structure 510 in which the first insulating layers 510A and the first conductive layers 510C are alternately stacked may be formed, and a second gate structure 560 in which the second insulating layers 560A and the second conductive layers 560C are alternately stacked may be formed. However, when the first and second sacrificial layers 510B and 560B each include a conductive material, a replacement process may be omitted. In such a case, the first and second stacks 510S and 560S may be used as the first and second gate structures 510 and 560, respectively.

Subsequently, a protective layer 570 may be formed on the second stack 560S. The protective layer 570 may prevent, in an embodiment, the channel structure 520, the support 540, and the slit structure 550 from being damaged in a subsequent process by covering the channel structure 520, the support 540, and the slit structure 550. Here, the protective layer 570 may include an insulating material such as oxide.

Subsequently, a mask pattern MP may be formed on the protective layer 570. The mask pattern MP may include a pattern for a region where third via holes VH3 are to be formed. Here, the region where the third via holes VH3 are to be formed may be a region between adjacent first via sacrificial layers 530S1.

Subsequently, the third via holes VH3 extending through the protective layer 570 and the second stack 560S may be formed. In a process of forming the third via holes VH3, in an embodiment, the protective layer 570 may prevent the channel structure 520, the support 540, and the slit structure 550 from being damaged. The third via holes VH3 may expose the second sacrificial layers 560B of the second stack 560S, respectively. A width of the third via holes VH3 may be substantially the same as the width of the first via holes VH1. Subsequently, third via sacrificial layers 580S may be formed by forming a sacrificial material such as carbon or tungsten in the third via holes VH3. Subsequently, the mask pattern MP may be removed.

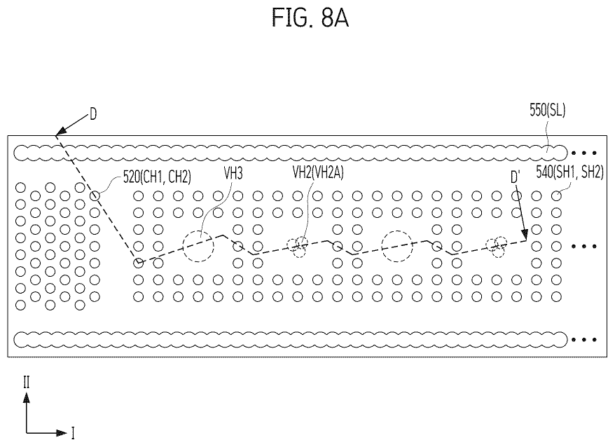

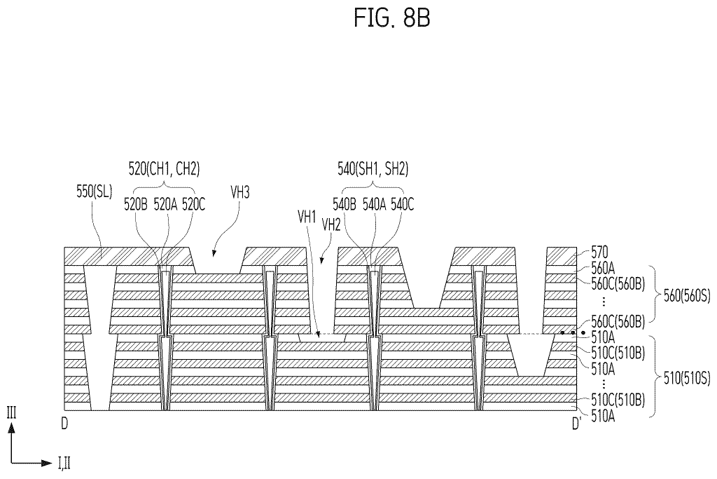

Referring to FIGS. 8A and 8B, openings exposing the second via sacrificial layers 530S2 may be formed through the protective layer 570. Subsequently, the first via hole VH1 and the preliminary second via holes VH2A may be reopened by removing the first and second via sacrificial layers 530S1 and 530S2 through the openings.

Subsequently, a second via hole VH2 may be formed. The second via hole VH2 may be formed by expanding the preliminary second via holes VH2A so that the preliminary second via holes VH2A are connected to each other. Here, a width of the second via hole VH2 may be smaller than the width of the first via hole VH1.

The third via holes VH3 may be reopened by removing the third via sacrificial layers 580S. When the first and second via sacrificial layers 530S1 and 530S2 are removed, the third via sacrificial layers 580S may be removed. In addition, when the second via hole VH2 is formed by expanding the preliminary second via holes VH2A, the third via holes VH3 may also be expanded. However, the present disclosure is not limited thereto, and the third via sacrificial layers 580S may be removed after the first and second via sacrificial layers 530S1 and 530S2 are removed. In addition, only the preliminary second via holes VH2A may be selectively expanded, and the third via holes VH3 might not be expanded.

According to an embodiment of the present disclosure, one second via hole VH2 may be formed by expanding the preliminary second via holes VH2A, and the first and second via holes VH1 and VH2 and the third via holes VH3 may be alternately formed in the horizontal direction. In other words, the first via holes VH1 having a relatively great width may be formed to be spaced apart from each other, and the third via holes VH3 may be formed between the second via holes VH2. Because the second via holes VH2 have the smaller width than the first via hole VH1, a space margin for forming the third via holes VH3 may be secured. In other words, by first forming the preliminary second via holes VH2A having a relatively small width, the space margin for forming the third via holes VH3 having a relatively great width may be secured. That is, when the third via holes VH3 having the relatively great width are formed to be continuously arranged, an interval between the third via holes VH3 should be great in order to secure the space margin for forming the third via holes VH3, and thus, in an embodiment, there is a limitation in improving the degree of integration of the semiconductor device, whereas according to an embodiment of the present disclosure, the third via holes VH3 having the relatively great width and the preliminary second via holes VH2A having the relatively small width are formed to be alternately arranged, and it is thus possible to improve the degree of integration of the semiconductor device while securing an interval between the third via holes VH3 having the relatively great width. Accordingly, in an embodiment, by adjusting an arrangement form of structures having a relatively great width, it is possible to utilize the space margin and improve the degree of integration of the semiconductor device.

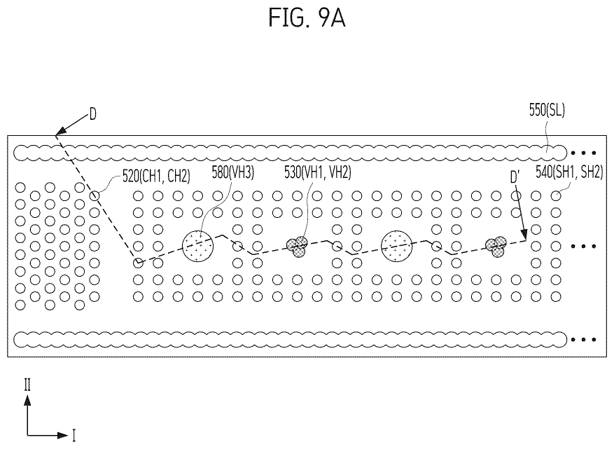

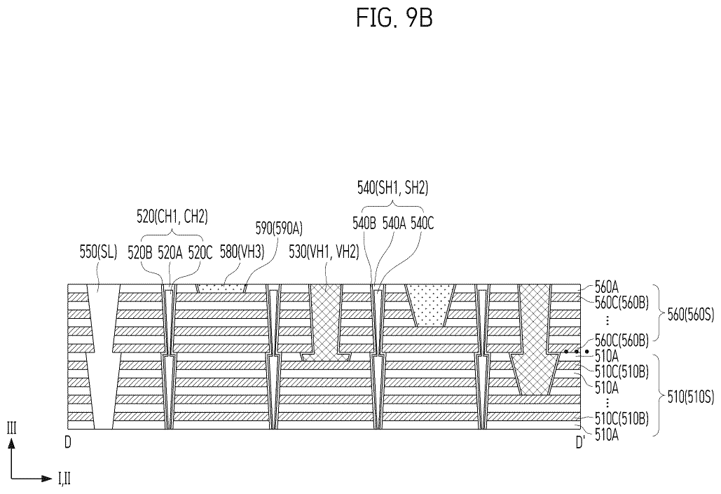

Referring to FIGS. 9A and 9B, a preliminary insulating spacer 590A may be formed in the first and second via holes VH1 and VH2 and the third via hole VH3. For example, the preliminary insulating spacer 590A may be conformally formed in the first, second, and third via holes VH1, VH2, and VH3. Subsequently, insulating spacers 590 may be formed by etching a lower surface of the preliminary insulating spacer 590A so that the first and second conductive layers 510C and 560C are exposed. Here, the insulating spacer 590 may include an insulating material such as oxide.

Subsequently, a first contact via 530 may be formed in the first and second via holes VH1 and VH2. The first contact vias 530 may be connected to the first conductive layers 510C of the first gate structure 510, respectively. Here, the first contact via 530 may include a conductive material such as tungsten.

A second contact via 580 may be formed in the third via hole VH3. When the first contact via 530 is formed, the second contact via 580 may be formed. The second contact via 580 may include a conductive material such as tungsten. Subsequently, the protective layer 570 may be removed.

According to the manufacturing method described above, when the first channel hole CH1 is formed, the first support hole SH1 and the first slit hole SLH1A may be formed. In addition, when the second channel hole CH2 is formed, the second support hole SH2, the second slit hole SLH2A, and the preliminary second via holes VH2A may be formed. Accordingly, in an embodiment, the manufacturing cost may be reduced by unifying manufacturing processes of the semiconductor device.

One second via hole VH2 may be formed by expanding the preliminary second via holes VH2A. Here, the second via hole VH2 may have a smaller width than the first via hole VH1. In such a case, a space margin may be secured between adjacent second via holes VH2, and the third via hole VH3 may be formed between the adjacent second via holes VH2. Accordingly, in an embodiment, the degree of integration of the semiconductor device may be improved.

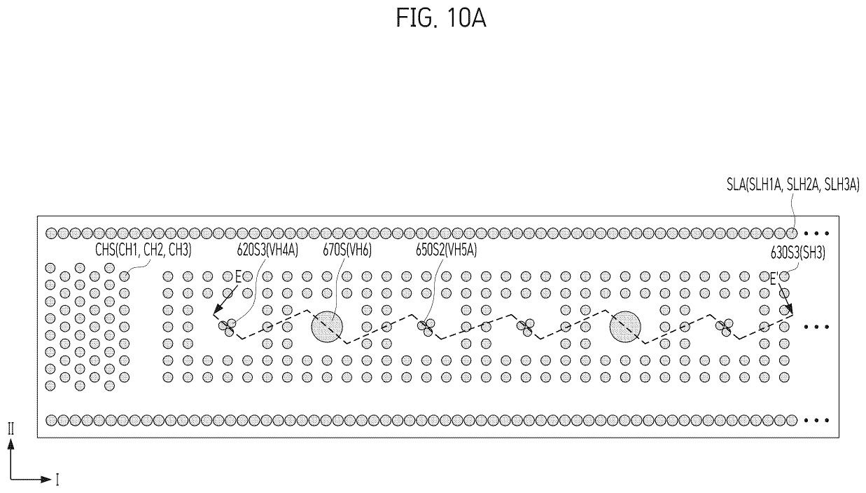

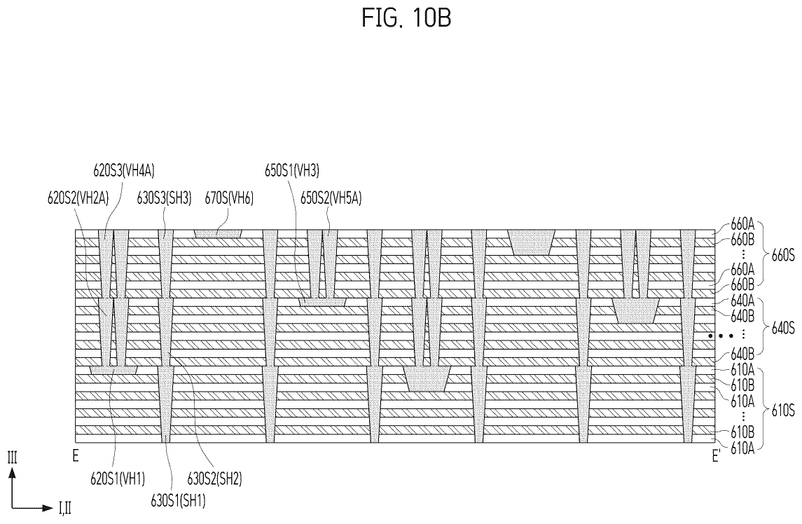

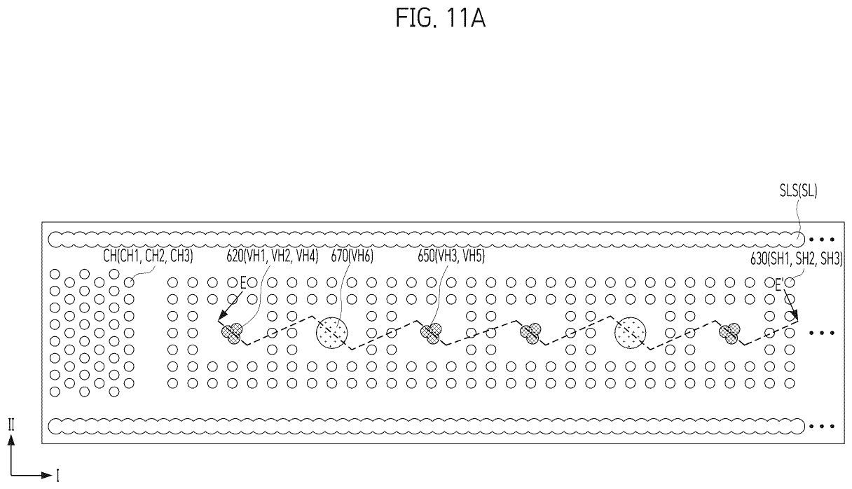

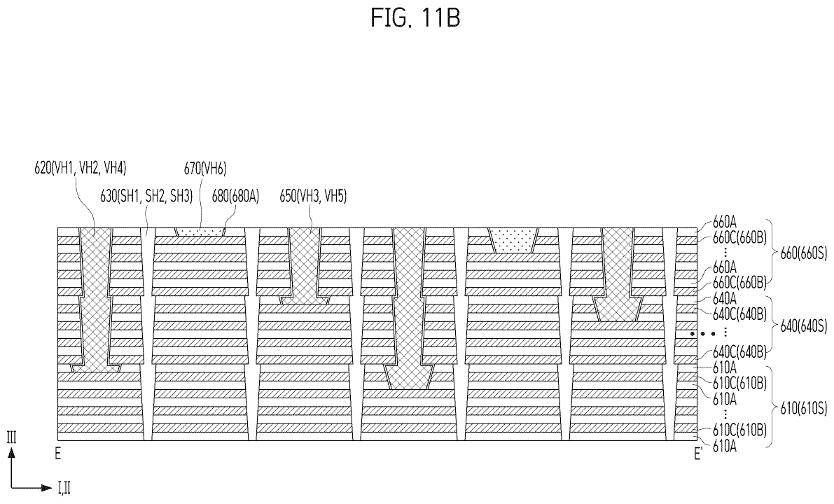

FIGS. 10A, 10B, 11A, and 11B are diagrams for describing a manufacturing method of a semiconductor device in accordance with an embodiment. FIGS. 10A and 11A are plan views, and FIGS. 10B and 11B are cross-sectional views taken along lines E-E′ of FIGS. 10A and 11A, respectively. Hereinafter, the content overlapping with the previously described content will be omitted.

Referring to FIGS. 10A and 10B, a first stack 610S may be formed by alternately stacking first insulating layers 610A and first sacrificial layers 610B. Subsequently, a first channel hole CH1, a first support hole SH1, a first slit hole SLH1A, and a first via hole VH1 extending through the first stack 610S may be formed.

Subsequently, a first channel sacrificial layer, a first support sacrificial layer 630S1, a first slit sacrificial layer, and a first via sacrificial layer 620S1 may be formed in the first channel hole CH1, the first support hole SH1, the first slit hole SLH1A, and the first via hole VH1, respectively.

Subsequently, a second stack 640S may be formed by alternately stacking second insulating layers 640A and second sacrificial layers 640B on the first stack 610S. Subsequently, a second channel hole CH2, a second support hole SH2, and a second slit hole SLH2A extending through the second stack 640S and connected to the first channel hole CH1, the first support hole SH1, and the first slit hole SLH1A, respectively, may be formed.

Preliminary second via holes VH2A extending through the second stack 640S and connected to the first via hole VH1 may be formed. Here, a width of the preliminary second via holes VH2A may be smaller than a width of the first via hole VH1.

Third via holes VH3 extending through the second stack 640S may be formed. Here, the third via holes VH3 may be formed at locations spaced apart from the preliminary second via holes VH2A. A width of the third via holes VH3 may be substantially the same as the width of the first via holes VH1.

Subsequently, a second channel sacrificial layer, a second support sacrificial layer 630S2, a second slit sacrificial layer, second via sacrificial layers 620S2, and a third via sacrificial layer 650S1 may be formed in the second channel hole CH2, the second support hole SH2, the second slit hole SLH2A, the preliminary second via holes VH2A, and the third via hole VH3, respectively.

Subsequently, a third stack 660S may be formed by alternately stacking third insulating layers 660A and third sacrificial layers 660C on the second stack 640S. Subsequently, a third channel hole CH3, a third support hole SH3, and a third slit hole SLH3A extending through the third stack 660S and connected to the second channel hole CH2, the second support hole SH2, and the second slit hole SLH2A, respectively, may be formed.

Preliminary fourth via holes VH4A extending through the third stack 660S and connected to the preliminary second via holes VH2A may be formed. Here, a width of the preliminary fourth via holes VH4A may be smaller than the width of the first via hole VH1.

Preliminary fifth via holes VH5A extending through the third stack 660S and connected to the third via hole VH3 may be formed. When the preliminary fourth via holes VH4A are formed, the preliminary fifth via holes VH5A may be formed. Here, a width of the preliminary fifth via holes VH5A may be smaller than the width of the third via hole VH3.

Sixth via holes VH6 extending through the third stack 660S may be formed. Here, the sixth via holes VH6 may be formed at locations spaced apart from the preliminary fourth via holes VH4A and the preliminary fifth via holes VH5A. For example, the sixth via hole VH6 may be formed between the preliminary fourth via holes VH4A and the preliminary fifth via holes VH5A. However, the present disclosure is not limited thereto, and the preliminary fourth via holes VH4A, the preliminary fifth via holes VH5A, and the sixth via hole VH6 may be formed to be sequentially arranged in the horizontal direction. A width of the sixth via holes VH6 may be substantially the same as the width of the first via holes VH1 and the third via holes VH3.

Subsequently, a third channel sacrificial layer, a third support sacrificial layer 630S3, a third slit sacrificial layer, fourth via sacrificial layers 620S3, fifth via sacrificial layers 650S2, and a sixth via sacrificial layer 670S may be formed in the third channel hole CH3, the third support hole SH3, the third slit hole SLH3A, the preliminary fourth via holes VH4A, the preliminary fifth via holes VH5A, and the sixth via hole VH6, respectively. Consequently, a channel sacrificial layer CHS may be formed in the first, second, and third channel holes CH1, CH2, and CH3, and a slit sacrificial layer SLA may be formed in the first, second, and third slit sacrificial layers SLH1A, SLH2A, and SLH3A.

Referring to FIGS. 11A and 11B, a channel structure CH, a support 630, a slit structure SLS, first, second, and third gate structures 610, 640, and 660, first, second, and third contact vias 620, 650, and 670, and insulating spacers 680 may be formed. They may be formed using a method of forming the channel structure 520, the support 540, the slit structure 550, the first and second gate structures 510 and 560, the first and second contact vias 530 and 580, and the insulating spacers 590 as described above with reference to FIGS. 7A, 8A, and 9A, and FIGS. 7B, 8B, and 9B. Hereinafter, a method of forming the first, second, and third contact vias 620, 650, and 670 will be described in detail.

For example, the first via hole VH1, the preliminary second via holes VH2A, and the preliminary fourth via holes VH4A may be reopened by removing the first, second, and fourth via sacrificial layers 620S1, 620S2, and 620S3. Subsequently, a second via hole VH2 and a fourth via hole VH4 may be formed by expanding the preliminary second via holes VH2A so that the preliminary second via holes VH2A are connected to each other and expanding the preliminary fourth via holes VH4A so that the preliminary fourth via holes VH4A are connected to each other. Here, widths of the second via hole VH2 and the fourth via hole VH4 may be smaller than the width of the first via hole VH1. Subsequently, the first contact via 620 may be formed in the first via hole VH1, the second via hole VH2, and the fourth via hole VH4.

The third via hole VH3 and the preliminary fifth via holes VH5A may be reopened by removing the third and fifth via sacrificial layers 650S1 and 650S2. Subsequently, a fifth via hole VH5 may be formed by expanding the preliminary fifth via holes VH5A so that the preliminary fifth via holes VH5A are connected to each other. When the preliminary fourth via holes VH4A are expanded, the preliminary fifth via holes VH5A may be expanded. A width of the fifth via hole VH5 may be smaller than the width of the third via hole VH3. Subsequently, the second contact via 650 may be formed in the third via hole VH3 and the fifth via hole VH5. When the first contact via 620 is formed, the second contact via 650 may be formed.

The sixth via hole VH6 may be reopened by removing the sixth via sacrificial layer 670S. Subsequently, the third contact via 670 may be formed in the sixth via hole VH6. When the first contact via 620 is formed, the third contact via 670 may be formed.

For reference, an embodiment for three stacks 610S, 640S, and 660S has been illustrated in FIGS. 10A, 10B, 11A, and 11B, but the present disclosure may also be applied to four or more stacks. In other words, in an embodiment, regardless of the number of stacks, via holes formed in the same stack and having a relatively great width may be formed to be spaced apart from each other, and via holes having a relatively small width may be formed on the via holes having the relatively great width. Here, the via holes having the small width may be formed in a different stack from the via holes having the great width. In such a case, a space margin may be secured in a region between the via holes having the small width, and thus, the via holes having the relatively great width may be formed in a different stack. In an embodiment, the space margin may be secured by combining such arrangement forms of the via holes with each other, and thus, the degree of integration of the semiconductor device may be improved.

According to an embodiment of the manufacturing method described above, even though the number of stacks increases, the space margin may be secured by combining the arrangement forms of the via holes having different widths with each other, and the degree of integration of the semiconductor device may be improved.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a first gate structure including first conductive layers;
a second gate structure located on the first gate structure and including second conductive layers;
first contact vias extending through the second gate structure and into the first gate structure and connected to the first conductive layers, respectively, and each first contact via including a lower via and upper vias merged with each other in a horizontal direction and connected to the lower via; and
second contact vias extending at least partially through the second gate structure and connected to the second conductive layers, respectively.

2. The semiconductor device of claim 1, wherein the first contact vias and the second contact vias are alternately arranged in the horizontal direction.

3. The semiconductor device of claim 1, wherein a width of an upper surface of the merged upper vias is smaller than a width of an upper surface of the lower via.

4. The semiconductor device of claim 1, wherein a width of an upper surface of the lower via is substantially the same as a width of an upper surface of each of the second contact vias.

5. The semiconductor device of claim 1, wherein the merged upper vias constitute irregularities on sidewalls of the first contact vias, respectively.

6. The semiconductor device of claim 1, wherein the number of upper vias are two or more.

7. The semiconductor device of claim 1, wherein the first contact vias each include an inflection portion located between the first gate structure and the second gate structure.

8. The semiconductor device of claim 7, wherein at the inflection portion, a width of the merged upper vias in the second gate structure is smaller than a width of the lower via in the first gate structure.

9. The semiconductor device of claim 1,
wherein the merged upper vias have a smaller width at a lower surface thereof than at an upper surface thereof, and
wherein the lower via has a smaller width at a lower surface thereof than at an upper surface thereof.

10. The semiconductor device of claim 1, further comprising slit structures extending through the first gate structure and the second gate structure.

11. The semiconductor device of claim 10, wherein each of the slit structures includes irregularities on sidewalls thereof.

12. The semiconductor device of claim 1, further comprising:
channel structures extending through the first gate structure and the second gate structure; and
supports spaced apart from the channel structures and extending through the first gate structure and the second gate structure.

13. The semiconductor device of claim 12, wherein the supports are located around the first contact vias and the second contact vias.

14. The semiconductor device of claim 12,
wherein the channel structures each include at least one of a channel layer, a memory layer surrounding the channel layer, and an insulating core located in the channel layer, and
wherein the supports each include at least one of a dummy channel layer, a dummy memory layer surrounding the dummy channel layer, and a dummy insulating core located in the dummy channel layer.

15. The semiconductor device of claim 1, further comprising:
a peripheral circuit;
a bonding structure located on the peripheral circuit;
a channel structure extending through the first gate structure and the second gate structure; and
a source structure located on the first gate structure and the second gate structure and connected to the channel structure.

16. A semiconductor device comprising:
a first gate structure including first conductive layers;
a second gate structure located on the first gate structure and including second conductive layers;
a third gate structure located on the second gate structure and including third conductive layers;
first contact vias each including a first lower via extending into the first gate structure and connected to each of the first conductive layers, respectively, and first upper vias extending through the second gate structure and the third gate structure, the first upper vias merged with each other in a horizontal direction, and the first upper vias connected to the first lower via;
second contact vias each including a second lower via extending into the second gate structure and connected to each of the second conductive layers, respectively, and second upper vias extending through the third gate structure, the second upper vias merged with each other in the horizontal direction, and the second upper vias connected to the second lower via; and
third contact vias extending at least partially through the third gate structure and connected to the third conductive layers, respectively.

17. The semiconductor device of claim 16, wherein a width of an upper surface of the merged first upper vias is substantially the same as a width of an upper surface of the merged second upper vias.

18. The semiconductor device of claim 16, wherein a width of an upper surface of the merged first upper vias is smaller than a width of an upper surface of the first lower via.

19. The semiconductor device of claim 16, wherein a width of an upper surface of the merged second upper vias is smaller than a width of an upper surface of the second lower via.

20. The semiconductor device of claim 16, wherein a width of an upper surface of the first lower via or a width of an upper surface of the second lower via is substantially the same as a width of an upper surface of each of the third contact vias, respectively.

21. The semiconductor device of claim 16,
wherein the merged first upper vias constitute irregularities on sidewalls of the first contact vias, respectively, and
wherein the merged second upper vias constitute irregularities on sidewalls of the second contact vias, respectively.

22. The semiconductor device of claim 16, wherein the number of first upper vias are two or more, and the number of second upper vias are two or more.

23. The semiconductor device of claim 16,
wherein the first contact vias each include a first inflection portion located between the first gate structure and the second gate structure and a second inflection portion located between the second gate structure and the third gate structure, and
wherein the second contact vias each include a third inflection portion located between the second gate structure and the third gate structure.

24. The semiconductor device of claim 23,
wherein at the first inflection portion, a width of the merged first upper vias in the second gate structure is smaller than a width of the first lower via in the first gate structure,
wherein in the second inflection portion, the width of the merged first upper vias in the second gate structure changes, and
wherein at the third inflection portion, a width of the merged second upper vias in the third gate structure is smaller than a width of the second lower via in the second gate structure.

25. The semiconductor device of claim 23, wherein the second inflection portion and the third inflection portion are located at a corresponding level.

26. The semiconductor device of claim 16, wherein the merged first upper vias have a smaller width at a lower surface thereof than at an upper surface thereof, and the first lower via has a smaller width at a lower surface thereof than at an upper surface thereof.

27. The semiconductor device of claim 16, wherein the merged second upper vias have a smaller width at a lower surface thereof than at an upper surface thereof, and the second lower via has a smaller width at a lower surface thereof than at an upper surface thereof.
